(19) United States
(12) Patent Application Publication
(10) Pub. No.: US 2003/0143377 A1
(43) Pub. Date: Jul. 31, 2003

(54) Display apparatus having a light shielding layer

(76) Inventors: Keiichi Sano, Anpachi-gun (JP); Tsutomu Yamada, Motosu-gun (JP)

Correspondence Address: Michael A. Cantor, Esq., CANTOR COLBURN LLP, 55 Griffin Road South, Bloomfield, CT, 06002, US

(21) Appl. No.: 10/353,646

(22) Filed: Jan. 29, 2003

(30) Foreign Application Priority Data
Jan. 30, 2002 (JP) 2002-21843

(51) Int. Cl. B32B 3/00

(52) U.S. Cl. 428/156

(57) ABSTRACT

A light shielding layer is formed over a substrate such as a glass substrate on which a silicon nitride layer as a blocking layer and a silicon oxide layer as an insulating layer having an interface state density lower than that of the blocking layer are formed on the light shielding layer and the glass substrate. An amorphous semiconductor layer which is an original material to be transformed into a polycrystalline semiconductor layer constituting a driving element is formed on the insulating layer having the lower interface state density and the amorphous semiconductor layer is polycrystallized by annealing, for example, laser-annealing to generate a polycrystalline semiconductor layer. The blocking layer reliably prevents impurities from entering the polycrystalline semiconductor layer from either the substrate side or the light shielding layer side. Further, because the polycrystalline semiconductor layer is formed on the insulating layer of which interface state density is low, fluctuations in characteristics of the driving element employing the polycrystalline semiconductor layer as an active layer can be avoided.

### BACKGROUND OF THE INVENTION

1. Field of the Invention

The present invention relates to a semiconductor display apparatus and a manufacturing method thereof. More specifically, it relates to a semiconductor display apparatus having a light shielding layer for blocking irradiation of light onto a driving element and to a manufacturing method thereof.

2. Description of the Related Art

As an example of a semiconductor display apparatus, a cross-sectional structure of a liquid crystal display apparatus according to a related art is shown in FIG. 1. This liquid crystal display apparatus is manufactured by the following processes.

First, by forming a film made of metal on a glass substrate 100 and patterning the formed metal film, a light shielding layer 101 is formed. Next, an insulating layer 102 made of silicon oxide (SiO₂) is formed into a film over the light shielding layer 101 and the glass substrate 100. Then, an amorphous silicon layer to be formed into a polycrystalline silicon (polysilicon) layer 110 is formed on the insulating layer 102 and irradiated with a laser to form the polycrystalline silicon layer 110. It should be noted here that the above-described insulating layer 102 is provided for insulating the conductive light shielding layer 101 from the polycrystalline silicon layer 110 as well as preventing the entry of impurities into the polycrystalline silicon layer 110. More specifically, by irradiating the glass substrate 100 with a laser where the amorphous silicon layer has been formed into a film, the temperature of both the amorphous silicon layer and the glass substrate 100 is raised for a short time. The elevated temperature causes that impurities contained in the glass substrate 100 to separate and seep out from the glass substrate 100, thereby adversely affecting the polycrystalline silicon layer 110.

After the polycrystalline silicon layer 110 is thus formed, an insulating layer 111 constituting a gate insulating layer and a gate 112 are sequentially formed on the polycrystalline silicon layer 110. A drain 110d, a channel 110c, and a source 110s of the polycrystalline silicon layer 110 are generated, for example, by doping impurities into the polycrystalline silicon layer 110. A thin film transistor TFT as a driving element for driving liquid crystal is thus generated. Further, the insulating layer 111 and the gate 112 are covered by an interlayer insulating layer 113 where contact holes 120 are opened to penetrate the interlayer insulating layer 113 and the insulating layer 111, the electrodes 121 are formed on the interlayer insulating layer 113 and contact to corresponding either the drain 110d or the source 110s through each of the contact holes 120.

Then, after forming a planarization layer 130 over the interlayer insulating layer 113 and the electrodes 121, a contact hole 131 penetrating the planarization layer 130 is formed. A transparent pixel electrode 140 are formed on the planarization layer 130 and make contact with one of the electrodes 121 through the contact hole 131.

As described above, the insulating layer 102 is preformed on an layer intervening between the glass substrate, on which has been formed the light shielding layer 101, and the amorphous silicon layer, which prevents impurities from entering the silicon layer from the glass substrate 100 while laser light is irradiated onto the amorphous silicon layer. There is, however, a possibility that the impurities contained in the light shielding layer 101 or existing on the surface of the light shielding layer 102 would diffuse on the insulating layer 102 during laser irradiation onto the amorphous silicon layer. Such diffusion seems to be due to the fact that laser irradiation onto the amorphous silicon layer causes temperature rises in not only the amorphous silicon layer but also the light shielding layer and the insulating layer. This is undesirable as any diffusion of impurities to the insulating layer 102 would negatively effect the quality of the resulting display apparatus.

### SUMMARY OF THE INVENTION

The present invention relating to a display apparatus having a driving element with a light shielding layer provided under the element and the features described below realizes a high-quality display is realized, without any adverse effects of a lower layer on an active layer of the driving element.

More specifically, according to the present invention, a display apparatus comprises a light shielding layer formed over a substrate, and a polycrystalline semiconductor layer formed over the light shielding layer and constituting a driving element. Further, in the display apparatus, a blocking layer and an insulating layer are formed between the light shielding layer and the polycrystalline semiconductor layer, the blocking layer formed on the side of the substrate to prevent impurities from diffusing and the insulating layer formed on the side of the polycrystalline semiconductor so as to make contact with the polycrystalline semiconductor layer, and the insulating layer having an interface state density between itself and the polycrystalline semiconductor layer lower than that between the blocking layer and said polycrystalline semiconductor layer.

With this structure, the blocking layer is able to preferably prevent material of the light shield layer and impurities existing on the surface of the light shield layer from diffusing while the polycrystalline semiconductor layer is generated by irradiating laser on an amorphous semiconductor layer. Further, by forming the polycrystalline semiconductor layer on an insulating layer the interface state density of which is lower than that of the blocking layer, the characteristics of the driving element configured by including the polycrystalline semiconductor layer can be appropriately maintained.

According to another aspect of the present invention, a display apparatus comprises a light shielding layer formed over a transparent substrate in a tapered-shape broadening toward the transparent substrate side, and a polycrystalline semiconductor layer formed over the light shielding layer and constituting a driving element. Further, in the display apparatus, a blocking layer and an insulating layer are formed between the light shielding layer and the polycrystalline semiconductor layer, the blocking layer formed on the side of the substrate to prevent impurities from diffusing and an insulating layer formed on the side of the polycrystalline semiconductor layer so as to make contact with the polycrystalline semiconductor layer, the insulating layer having an interface state density between itself and the polycrystalline semiconductor layer lower than that between the blocking layer and the polycrystalline semiconductor layer.

By thus forming the light shielding layer in a tapered shape in which the edges of the light shielding layer are broader toward the transparent substrate side, differences in levels between a region on which the light shielding layer is formed and the other regions can be reduced to thereby prevent problems such as formation of cracks during formation of films such as the blocking layer, the insulating layer, or the like.

According to another still aspect of the present invention, in the above-described display apparatus, the insulating layer comprises silicon oxide and the blocking layer comprises silicon nitride.

According to still another aspect of the present invention, in the above display apparatus, either a constant voltage or a signal identical to that of a scanning line for scanning the driving element formed on the upper layer of the light shielding layer is applied to the light shielding layer.

In a state wherein the light shielding layer is not connected to any object, the potential of the light shielding layer becomes unstable, and charging/holding operation of the display signal executed by the transistor provided over the light shielding layer unstably fluctuates on a pixel-by-pixel basis, thereby decreasing display quality. By maintaining a constant potential for the light shielding layer constant, stability of the signal charging/holding operation maintained, thereby preventing any reduction in display quality.

Further, by connecting the light shielding layer to the scanning line so as to establish the light shielding layer at the potential identical to that of the scanning signal, the efficiency of charging of the transistor provided over the light shielding layer can be enhanced, making it possible to support high-speed driving requiring such capability.

According to yet another aspect of the present invention, an active matrix type display apparatus comprises a pixel region and a driver region both formed over the same substrate, a plurality of pixels are arranged in the pixel region, each of the plurality of pixels comprises a pixel region transistor and a display element, and the driver region includes a plurality of driver region transistors outputting a signal for driving each of the pixels in the pixel region. In this active matrix type display apparatus, the same polycrystalline semiconductor material may be used for active layers of the pixel region transistor and the driver region transistor both of which are formed as top gate type transistors on the substrate. Further, a blocking layer and an insulating layer may be formed, in that order from the substrate side, under the polycrystalline semiconductor active layers of the pixel region transistor and the driver region transistor, the blocking layer for preventing impurities from diffusing and an insulating layer formed so as to make contact with the polycrystalline semiconductor active layer and having an interface state density between itself and the polycrystalline semiconductor active layer lower than that between the blocking layer and the polycrystalline semiconductor layer, and a light shielding layer is provided under the polycrystalline semiconductor active layer of the pixel region transistors so as to sandwich the insulating layer and the blocking layer in between.

By thus eliminating the light shielding layer from the driver region but forming the layer on the pixel region, and forming the same insulating layer and the blocking layer under the polycrystalline semiconductor active layers formed on the driver region and the pixel region, it becomes possible to obtain a polycrystalline semiconductor formed having different grain sizes each appropriate to either one of the driver and pixel regions by, for example, annealing for polycrystallization under the same condition. On the pixel region, it is also possible to reliably prevent leakage of impurities into the driving element from the light shielding layer side and to prevent fluctuation in characteristics and leakage currents caused by irradiation of extraneous light incident from the substrate side.

According to a still further aspect of the present invention, in the above active matrix type display apparatus, the light shielding layer has tapered sides which broaden toward the substrate side.

The tapered side surfaces are capable of reliably preventing formation of cracks in the upper layers.

According to another aspect of the present invention, a manufacturing method of a display apparatus comprises the steps of forming a light shielding layer over a substrate, forming a blocking layer over the substrate for preventing impurities from diffusing so as to cover the light shielding layer, forming an insulating layer having an interface state density with the polycrystalline semiconductor lower than that between the blocking layer and the polycrystalline semiconductor, over the blocking layer, forming an amorphous semiconductor layer on the insulating layer, polycrystallize the amorphous semiconductor layer by annealing, and forming a driving element employing the obtained polycrystalline semiconductor layer as an active layer of a driving element.

According to still another aspect of the present invention, in the above-described method of manufacturing a display apparatus, steps from the step of forming the blocking layer to the step of forming the amorphous semiconductor layer are carried out -in sequence and in a single apparatus.

Such sequential completion prevents entry of impurities while the semiconductor layer constituting the active layer of the driving element, the active layer which tends to wield influence over the driving element, and other layers provided in the vicinity of the semiconductor layer are formed, thereby enabling increased element reliability.

According to yet another aspect of the present invention, in the above method of manufacturing a display apparatus, the light shielding layer is patterned in the pixel region and the driver region both formed on the same substrate so as to be selectively left on an underlying region of the region where the polycrystalline semiconductor layer constituting the driving element in the pixel region is formed, but removed from a region on which the polycrystalline semiconductor constituting the driving element in the driver region, and polycrystallized at the same time from the same material with the driving element in the pixel region are formed.

### BRIEF DESCRIPTION OF THE DRAWINGS

FIG. 1 shows a cross-sectional structure in a pixel region of a liquid crystal display apparatus according to a related art;

FIG. 2A is a schematic diagram showing a circuit configuration of a liquid crystal display apparatus according to an embodiment of the present invention;

FIG. 2B is a schematic plan view showing the structure of one pixel of the liquid crystal display apparatus according to the embodiment of the present invention;

FIG. 2C is a schematic cross-sectional view of the structure shown in FIG. 2B along the line A-A;

FIG. 2D is a schematic cross-sectional view illustrating differences in structures between a driver region and a pixel region in the liquid crystal display apparatus according to an embodiment of the present invention;

FIGS. 3A, 3B, 3C, 3D, and 3E are drawings showing manufacturing procedures for realizing the liquid crystal display apparatus according to the embodiment of the present invention;

FIG. 4 is a schematic drawing showing a film forming device having a multi-chamber structure used in the embodiment of the present invention;

FIGS. 5A, 5B, 5C, 5D, and 5E are drawings showing subsequent manufacturing procedures subsequent to those illustrated FIG. 3E, and

FIG. 6 is a schematic diagram showing a circuit configuration of another display apparatus according to the embodiment of the present invention.

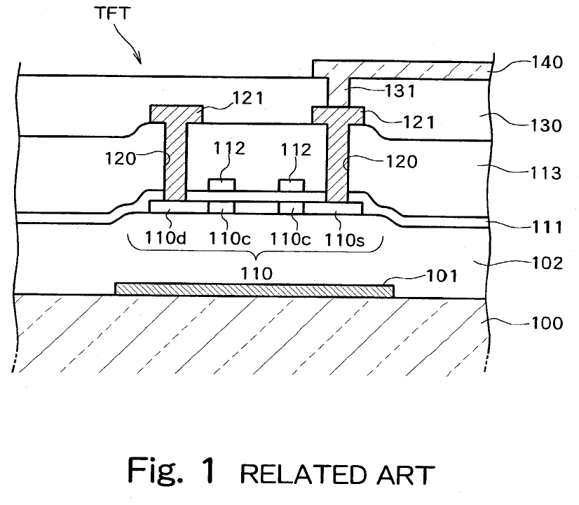

### DESCRIPTION OF THE PREFERRED EMBODIMENT

Referring to drawings, an embodiment in which a semiconductor display apparatus and a manufacturing method thereof according to the present invention are applied to aliquid crystal display apparatus will be described below.

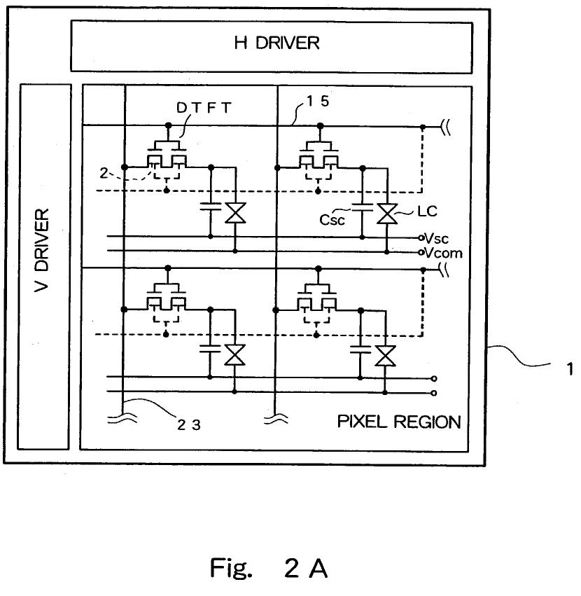

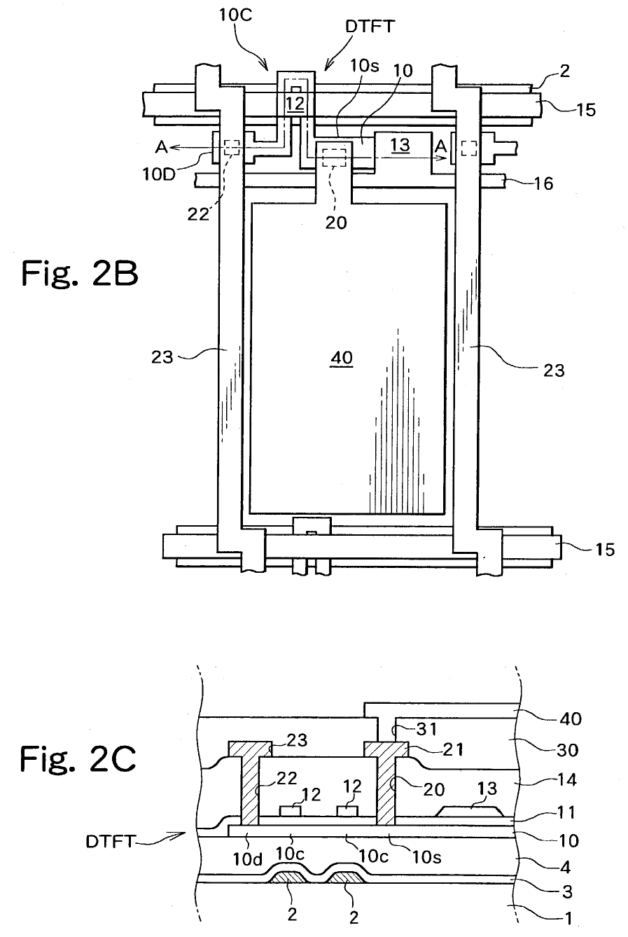

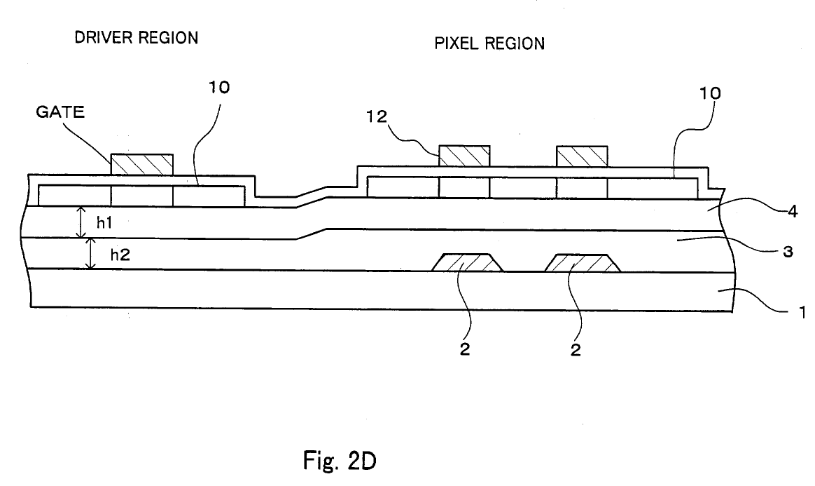

FIG. 2A is a schematic diagram of a circuit configuration of a liquid crystal display apparatus according to the present embodiment, and shows a pixel region formed on a substrate and driver regions formed in the vicinity of the pixel region on the same substrate. FIG. 2B is a plan view showing a structure of one pixel (dot), which is the minimum display unit in the pixel region in the liquid crystal display apparatus as shown in FIG. 2A.

A drain 10d, a channel 10d, and a source 10s for a top gate type double gate transistor DTFT shown in FIG. 2B are formed in a polycrystalline silicon layer 10. A data (drain) signal line 23 is connected to the drain 10d of the transistor DTFT through a contact hole 22 and a gate 12 is integrally formed with a gate signal line 15. On the other hand, a transparent pixel electrode 40 is connected to the source 10s of the transistor DTFT through a contact hole 20.

A display signal (image signal) impressed from an H driver to the corresponding data signal line 23 is applied to the pixel electrode 40 via the drain 10d and the source 10s when the transistor DTFT is turned to the ON state by a scanning signal (selection signal) applied from a V driver to the gate 12 through the corresponding gate signal line 15. It should be noted that, in this example, the polycrystalline silicon layer 10 extends from a region where the source 10s is formed to the outside (an adjoining pixel side), and the extended region forms a capacitor in conjunction with an electrode 13 formed above the extended region using a material identical to that of a gate. The electrode 13 of the capacitor is connected to another electrode 13 through a capacitor line 16. By providing the capacitor to each pixel as described above, the image signal output to the source 10s can be retained for an adequate time period for driving the appropriate pixel electrode 40.

A light shielding layer 2 is formed under the above-described transistor DTFT within the pixel region. The light shielding layer 2 is formed along the gate signal line 15 and has a width broader than that of the gate signal line 15. Accordingly, light incident from below the transistor DTFT, i.e. from the substrate 1 side, is blocked by the light shielding layer 2 to thereby protect the channel 10c from irradiation with light. It should be noted here that the capacitor line 16 is connected to the light shielding layer 2 through a voltage supply line which is not illustrated in the figure.

FIG. 2C shows a cross-sectional view of the structure taken along the line C-C in FIG. 2B. As shown in FIG. 2C, the above-described light shielding layer 2 configured by a film made of refractory metal (high melting point metal) such as, for example, chromium (Cr), molybdenum (Mo), titanium (Ti), or tungsten (W) is formed on the glass substrate 1. A silicon nitride (SiN) layer 3 and a silicon oxide (SiO₂) layer 4 are formed, in that order, on the light shielding layer 2 and a polycrystalline silicon layer 10 is formed on the silicon oxide layer 4. By doping impurities into the polycrystalline silicon layer 10, predetermined conductivity is added to form the drain 10d, the channel 10c, and the source 10s. An insulating layer 11 comprising laminated films made of silicon oxide (SiO₂) and silicon nitride (SiN) and serving as the gate insulating layer and as a dielectric film of the capacitor of the transistor DTFT is formed on the polycrystalline silicon layer 10. Further, on the insulating layer 11, the gate 12 and the electrode 13 may be configured by a film made of refractory metal such as, for example, chromium (Cr), molybdenum (Mo), titanium (Ti), or tungsten (W).

An interlayer insulating layer 14 formed by laminating a silicon nitride (SiN) layer and a silicon oxide (SiO₂) layer is formed covering all of the insulating layer 11, the gate 12, and the electrode 13. Then, on the interlayer insulating layer 14, contact holes 20, 22 are formed on regions corresponding to the source 10s and the drain 10d of the transistor DTFT, respectively. Contact between the source 10s and the electrode 21 is established through the contact hole 20 and contact between the drain 10d and the data signal line 23 is established through the contact hole 22. The data signal line 23 and the electrode 21 are formed by laminating films of molybdenum (Mo), aluminum (Al), and molybdenum (Mo).

A planarization layer 30 made of organic resin is formed covering the interlayer insulating layer 14, the drain signal line 23, and the electrode 21. A contact hole 31 is formed penetrating the planarization layer 30 so as to establish electrical contact between the electrode 21 and the pixel electrode 40 made of ITO (Indium Tin Oxide).

In the above-described display apparatus, the silicon nitride layer 3 is formed on the light shielding layer 2 as a blocking layer for preventing the impurities from diffusing on upper layers and silicon oxide layer 4 is formed as an upper layer of the blocking layer as an insulating layer having an interface state density between itself and the polycrystalline silicon layer 10 lower than that between the blocking layer 3 and the polycrystalline silicon layer 10 in sequence. This structure makes it possible to maintain desired display quality, even in a case wherein the polycrystalline silicon layer 10 is generated through a process of irradiating the amorphous silicon layer located above the light shielding layer 2 with laser light.

More specifically, because the silicon nitride layer 3 is formed on the light shielding layer 2, diffusion of the impurities in the material of the light shielding layer 2 and on the surface of the light shielding layer 2 to the silicon oxide layer 4 during laser irradiation of the amorphous silicon layer can be prevented. Further, because the polycrystalline silicon layer 10 is formed on the silicon oxide layer 4 having an interface state density lower than that of the silicon nitride layer 3, it is also possible to appropriately maintain the characteristics of the transistor DTFT configured by using the polycrystalline silicon layer 10. On the other hand, when the polycrystalline silicon layer 10 is formed directly on the silicon nitride layer 3, fluctuations of the characteristics such as changes in threshold values of the transistor DTFT which is emerged as, for example, increased trap of a carrier can be introduced due to the higher interface state density of the silicon nitride layer 3.

According to the present embodiment, the edges (side walls) of the light shielding layer 2 are formed in a tapered shape which broadens towards the glass substrate 1. Such a tapered shape helps to reduce differences in levels between the portion on which the light shielding layer 2 is formed and other portions, thereby preventing problems such as, for example, generation of cracks when the silicon nitride layer 3 and the silicon oxide layer 4 are formed over the glass substrate 1.

It should be noted that the driving element (thin film transistor) using the polycrystalline silicon layer same as that of each pixel TFT (DTFT) in the above-described pixel region as an active layer may also be employed in the H and V drivers each driving the pixel region depicted in FIG. 2A. In such a case, a structure , such as that shown in FIG. 2D, in which no light shielding layer is provided under the transistor in the driver, may be employed. In the driver region, a requirement for the transistor is high speed operation and it is therefore preferable that the polycrystalline silicon have a large grain size. On the other hand, requirements for the transistor in the pixel region are smaller leakage currents and smaller variations in characteristics in each pixel. In order to achieve these requirements in the pixel region, it is necessary that factors which affect the characteristics, such as the number of grain boundaries, be as uniform as possible for all TFTs, and this requirement takes precedence over larger gain size. In a case where amorphous silicon is annealed for transformation into polycrystalline silicon by laser irradiation under the same condition, the amorphous silicon demonstrates a tendency for the thermal diffusion speed to increase when it is located above a metal light shielding having high thermal conductivity, such that the finally obtained grain size becomes smaller. Accordingly, by providing no light shielding layer under the TFT in the driver region (by removing the light shielding layer from under the TFT when the light shielding layer is patterned), and providing the light shielding layer only under the TFT in the pixel region, polycrystalline silicon can be formed in grain sizes which appropriately vary between the drain region and the pixel region when amorphous silicon is annealed under the same condition in both the driver and the pixel regions. In order to obtain grain sizes appropriate to each of the regions when annealed under the same conditions (by a laser of equal power), it is desirable to optimize thermal capacity caused by the insulating layer and the blocking layer by adjusting the thickness of the insulating layer and the blocking layer located under the polycrystalline silicon layer, as will be described below.

Next, a procedure for manufacturing a liquid crystal display apparatus according to the present embodiment will be described.

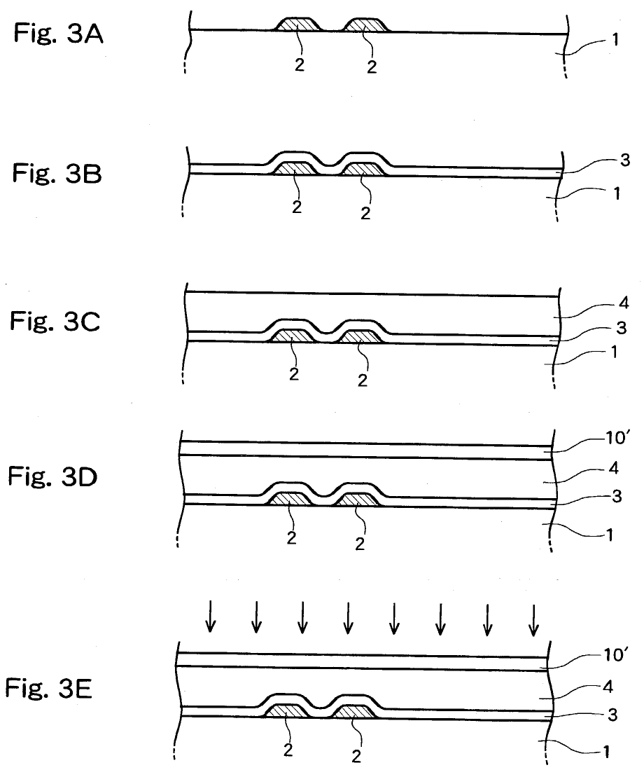

In a series of manufacturing processes, the above-described refractory metal film having a thickness of, for example, 200 nm is formed by a sputtering method and patterned so as to form the light shielding layer 2 on the glass substrate 1, as shown in FIG. 3. During the patterning, the light shielding layer 2 is formed in a tapered shape in which the edges (side walls) are broadened toward the glass substrate 1 side as described above.

In a case where no light shielding layer is provided under the transistor in the driver region as described above, the refractory metal layer may be removed from regions to be provided with the driver during patterning of the refractory metal layer. When the light shielding layer is formed in the driver region, the refractory metal layer may, of course, be left in a desired pattern.

Next, the silicon nitride layer 3 and other layers are formed in another apparatus different from the spattering apparatus used for forming the light shielding layer 2. More specifically, in this example, after the substrate on which the light shielding layer 2 is patterned is placed in a CVD (Chemical Vapor Deposition) apparatus, silicon nitride is formed using a plasma CVD method into a film with a thickness of, for example, 50 nm as shown in FIG. 3B so as to form the silicon nitride layer 3 as a blocking layer. Subsequently, using the same plasma CVD method, silicon oxide is formed into a film with a thickness of, for example, 130 nm so as to form the silicon oxide layer 4 as an insulating layer as shown in FIG. 3C. Further, an amorphous silicon layer 10′ is formed in thickness of, for example, 50 nm using the plasma CVD method as shown in FIG. 3D.

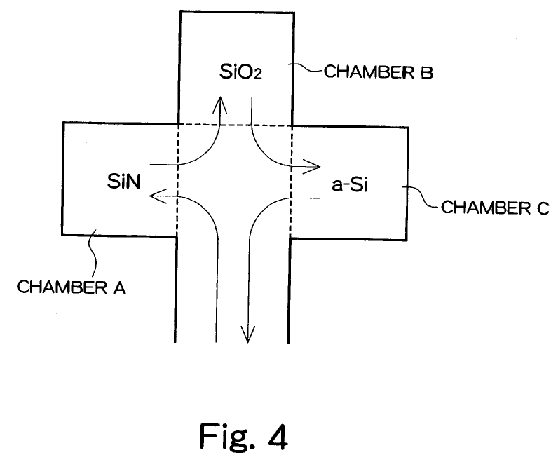

In this embodiment, these forming processes from the silicon nitride layer 3 to the amorphous silicon layer 10′ as shown in FIGS. 3B, 3C, and 3D are successively executed in the same apparatus (the CVD apparatus). More specifically, by employing a multi-chamber apparatus comprising a plurality of chambers (chambers A, B, C) as schematically illustrated in FIG. 4, film formation processes from the silicon nitride layer 3 to the amorphous silicon layer 10′ can be successively carried out in a vacuum to prevent impurities from entering the layers from the silicon nitride layer 3 to the amorphous silicon layer 10′.

After the sequential film formation processes from the silicon nitride layer 3 to the amorphous silicon layer 10, the glass substrate 1 on which the layers including the amorphous silicon layer 10′ are formed is removed from the apparatus used for film formation. Then, as shown in FIG. 3E, by irradiating laser onto the amorphous silicon layer 10′ for polycrystallizing annealing, the amorphous silicon layer 10′ is polycrystallized.

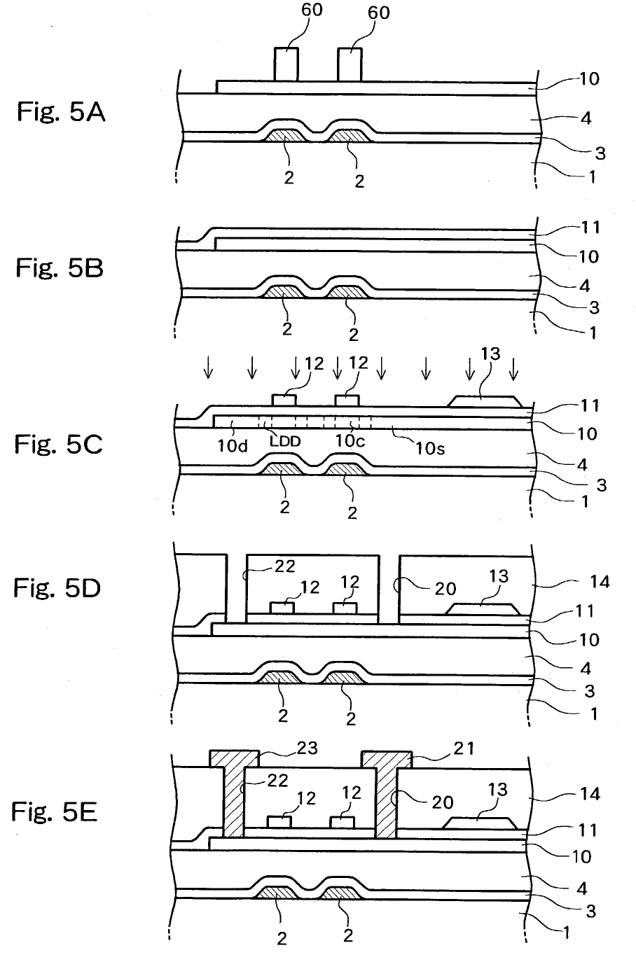

Then, as shown in FIG. 5A, the resulting polycrystallized layer is patterned to form the polycrystalline silicon layer 10, to which approximately 1×10¹³ atoms/cm² of boron or phosphorus is doped, followed by 1×10¹⁵ atoms/cm² of phosphorus is doped through a resist mask 60. After removing the resist mask 60, by lamination of films with a thickness of, for example, 130 nm made of silicon oxide (SiO₂) and with a thickness of, for example, 50 nm made of silicon nitride (SiN) using the plasma CVD method, the insulating layer 11 is formed as shown in FIG. 5B. Then, as shown in FIG. 5C, in order to form the above-described gate 12, the electrode 13, and other structures, a refractory metal film having a thickness of, for example, 200 nm is formed and then patterned. Next, approximately 1×10¹³ atoms/cm² of phosphorus and other elements is doped into the polycrystalline silicon layer 10 using the patterned gate 12 as a mask to form LDDs (Lightly Doped Drains) between the channel 10c and the drain 10d and between the channel 10c and the source 10s.

Subsequently, as shown in FIG. 5D, films with a thickness of, for example, 100 nm of silicon nitride and with a thickness of, for example, 500 nm of silicon oxide are laminated using the plasma CVD method to form the interlayer insulating layer 14. Then, the contact holes 20, 22 are opened in the insulating layer 11 and the interlayer insulating layer 14. As shown in FIG. 5E, films with a thickness of, for example, 100 nm of molybdenum (Mo), with a thickness of, for example, 400 nm of aluminum (Al), and with a thickness of, for example, 100 nm of molybdenum (Mo) are laminated to form the gate signal line 15, the electrode 21, and other structures on which the planarization layer 30 as shown in 2C is formed, and other processes are performed as appropriate so as to obtain the display apparatus shown in FIGS. 2B, 2C, and other figures.

According to the above-described embodiment, the following effects can be obtained:

(i) The structure of the silicon nitride layer 3, the silicon oxide layer 4, and the polycrystalline silicon layer 10 laminated over the light shielding layer 2 enables the silicon nitride layer 3 to preferably prevent impurities in and on the light shielding layer 2 2 from defusing to the silicon oxide layer 4 while the amorphous silicon 10′ is being irradiated with laser light for transformation into the polycrystalline silicon layer 10. Further, by forming the polycrystalline silicon layer 10 on the silicon oxide layer 4 of which interface state density is lower than that of the silicon nitride layer 3, it also becomes possible to appropriately maintain the characteristics of the transistor DTFT configured by using the polycrystalline silicon layer 10.

(ii) Because the light shielding layer 2 is formed having a tapered shape which widens towards the glass substrate 1 side, differences in level between a portion of the glass substrate 1 on which the light shielding layer 2 is formed and other parts of the glass substrate 1 can be reduced to thereby prevent problems such as, for example, generation of cracks during formation of the silicon nitride layer 3 or the silicon oxide layer 4.

(iii) Because formation of films from the silicon nitride layer 3 to the amorphous silicon layer 10′ can be successively performed in a single apparatus, the layers can be protected from exposure to the external atmosphere during the film formation, with a result that impurities can be prevented from entering these layers.

The above embodiment may be modified as follows:

Materials given as examples in the above description of the embodiment may be changed as appropriate. For example, the data signal line 23, the electrode 21 or the like may be made of either one of aluminum (Al), aluminum silicon (Al—Si), and copper (Cu), or formed by laminating films made of those listed above and made of refractory metal such as molybdenum (mo), titanium (Ti) or the like. As a substitute for the glass substrate 1, any transparent substrates such as a transparent plastic substrate may be utilized.

Film thicknesses described above may be modified in consideration given to film forming speeds, time for forming contact holes, or the like. For example, the film thickness of the silicon oxide layer 4 may be specified to a value between 50 nm and 4,000 nm and the silicon nitride layer 3 to a value between 50 nm and 2,000 nm.

It should be noted that in order to obtain a polycrystalline silicon layer formed with different grain sizes, each appropriate to either the driver or the pixel regions, by laser-annealing the amorphous silicon for polycrystallizing under the same condition in both the driver and the pixel regions and without forming the light shielding layer of metal in the driver region, it is preferable to determine the thicknesses of the blocking layer and the insulating layer with consideration given to heat leakage from the light shielding layer in the pixel region where the light shielding layer made of metal is formed under the polycrystalline silicon layer. More specifically, because the range of optimum energy values capable of providing appropriate grain sizes when amorphous silicon is polycrystallized by laser-annealing is relatively narrow, it is preferable to determine the thicknesses of the blocking layer and of the insulating layer such that the amount of thermal leakage in the driver region where the polycrystalline silicon layer is formed above the blocking layer and the insulating layer on the glass substrate with no light shielding layer formed under the polycrystalline silicon layer is relatively close to, or approximately equal to that in the pixel region where the light shielding layer having a large thermal leakage is formed under the polycrystalline silicon layer. In order to achieve this result, each of the layers may be established as follows. When film thickness h2 of the silicon nitride layer 3 as a blocking layer is 50 nm, it is preferable to specify thickness h1 of the silicon oxide layer 4 to a value equal to or larger than 200 nm. Alternatively, when thickness h1 of the silicon oxide layer 4 is 130 nm, it is preferable to specify thickness h2 of the silicon nitride layer 3 to a value equal to or larger than 100 nm. The thicknesses of the two silicon nitride and oxide layers are not limited to those described above. Although materials and the thicknesses of the blocking and insulating layers are not limited to those described above, it is desirable to form the two layers in the thicknesses which enable to establish wider spacing between the amorphous silicon layer and the light shielding layer of metal and to block heat from escaping when laser is irradiated on the amorphous silicon layer.

As a substitute for the laminated structure comprising the light shielding layer 2, the silicon nitride layer 3, the silicon oxide layer 4, and the polycrystalline silicon layer 10, other films may be provided between the light shielding layer 2 and the silicon nitride layer 3, or between the silicon nitride layer 3 and the silicon oxide layer 4. For example, films with low permittivity may preferably be used to thereby enable a suppressed capacitance between the light shielding layer 2 and the polycrystalline silicon layer 10.

An arbitrary blocking layer capable of preventing the impurities contained in the material and existing on the surface of the light shielding layer from diffusing during laser irradiation onto the amorphous silicon layer 10′ may be used instead of the above-described silicon nitride layer 3. Similarly, an arbitrary insulating layer having the interface state density lower than that of the above blocking layer may be used instead of the above-described silicon oxide layer 4.

In order to apply a constant voltage to the light shielding layer, the light shielding layer is, in the above example, connected to the capacitor line (electrode) so as to apply Vsc as one of the control voltages applied to each pixel. Alternatively, the light shielding layer may be connected to a common electrode which is opposed to the pixel electrode sandwiching liquid crystal in between to apply a common electrode potential Vcom. Instead of supplying the constant voltage to the light shielding layer, a periodically-varying voltage may be applied by connecting the light shielding layer to, for example, the gate signal line. In such a case, by connecting the light shielding layer to the gate signal line for scanning the transistor formed above the light shielding layer, it becomes possible to obtain the structure in which the same signal is applied to the light shielding layer and the gate signal line. Because a constant potential of the light shielding layer can cause fluctuation in the characteristics of the TFT formed above the light shielding layer and therefore possibly reduce display quality, to avoid this possibility, the potential of the light shielding layer may be connected to the potential of the gate.

The driving element is not limited to the double gate transistor DTFT as described above.

Application of the present invention is not limited to a liquid crystal display apparatuses as described above, and the present invention may also be applied to any semiconductor display apparatuses comprising a polycrystalline semiconductor layer generated by irradiating laser onto an amorphous semiconductor layer provided on a light shielding layer.

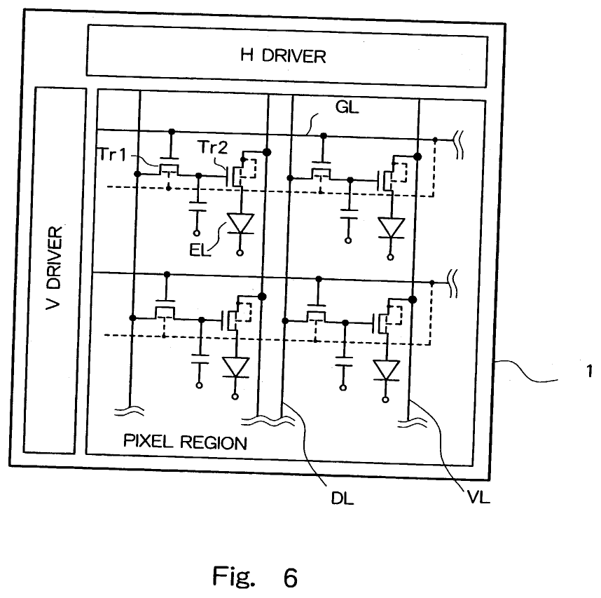

More specifically, an active matrix type electroluminescence display apparatus as shown in FIG. 6, for example, may incorporate the present invention to achieve similar effects. In the EL display apparatus of FIG. 6, it is possible to adopt the structure in which the light shielding layer is not formed under the TFT in the H, V driver regions similarly to the above-described example. With such a structure, the active layer (polycrystalline silicon layer) of the TFT is formed on the laminated structure comprising the blocking layer and the insulating layer, the light shielding layer is formed under the TFTs (Tr1, Tr2) in the pixel region, and the blocking layer and the insulating layer are formed in between the light shielding layer and the active layer (polycrystalline silicon layer) of the pixel region TFTs. An EL element (OLED) connected to the pixel TFT (Tr2) may be configured by laminating a first electrode defined by, for example, the ITO pixel electrode 40 depicted in FIG. 2C, an organic emissive element layer having a multi-layer or single layer structure, and a second electrode made of metal opposing to the first electrode in sequence. In FIG. 6, VL is a power line for supplying currents according to displayed content to the EL element through Tr2 in the pixel TFT.

In the configuration shown in FIG. 6, the metal layer (light shielding layer) provided under Tr1 is specific to the gate potential (G) and the metal layer (light shielding layer) provided under Tr2 is connected to a power source potential (VL) for electroluminescence of which voltage is almost constant. The connection on Tr2 has the effect of causing a change in the efficiency of a current of Tr2 in a dropping direction.

The connections of the metal layers of Tr1, Tr2 are not limited to those described above. For example, when the high-speed driving as described above is not required, the metal layers may be connected to a constant-voltage potential of, for example, the capacitor line (Vsc), and when the larger current efficiency is required, they may be provided with a gate voltage.

Further, combinations between a voltage applied to the metal layer under Tr1 and a voltage applied to the metal layer under Tr2 are listed in the following table where G, VL, Vsc represent a gate voltage, an EL power source voltage, a capacitor line voltage, respectively.

TABLE

| | Tr1 | Tr2 | Tr1 | Tr2 | Tr1 | Tr2 |
|---|---|---|---|---|---|---|
| Applied | G | G | Vsc | G | VL | G |
| Voltage | G | VL | Vsc | VL | VL | VL |
| | G | Vsc | Vsc | Vsc | VL | Vsc |

What is claimed is:

1. A display apparatus comprising:
a light shielding layer formed over a substrate, and
a polycrystalline semiconductor layer which is formed over the light shielding layer and constitutes a driving element; wherein
a blocking layer and an insulating layer are formed between said light shielding layer and said polycrystalline semiconductor layer, said blocking layer formed on a side of said substrate to prevent impurities from diffusing and said insulating layer formed on a side of said polycrystalline semiconductor so as to make contact with the polycrystalline semiconductor layer, and said insulating layer having an interface state density between said insulating layer and said polycrystalline semiconductor layer being lower than that between said blocking layer and said polycrystalline semiconductor layer.

2. A display apparatus according to claim 1, wherein said insulating layer comprises silicon oxide and said blocking layer comprises silicon nitride.

3. A display apparatus according to claim 1, wherein either a constant voltage or a signal identical to that of a scanning line for scanning the driving element formed on the upper layer of the light shielding layer is applied to said light shielding layer.

4. A display apparatus according to claim 3, wherein said constant voltage is a control voltage applied to the pixels having said driving element.

5. A display apparatus comprising:
a light shielding layer formed over a transparent substrate in a tapered shape broadening toward the transparent substrate side,
a polycrystalline semiconductor layer formed over the light shielding layer and constituting a driving element, and
a blocking layer and an insulating layer formed between said light shielding layer and said polycrystalline semiconductor layer, said blocking layer formed on a side of said substrate to prevent impurities from diffusing and said insulating layer formed on a side of the polycrystalline semiconductor layer so as to make contact with said polycrystalline semiconductor layer, said insulating layer having an interface state density between said insulating layer and said polycrystalline semiconductor layer being lower than that between said blocking layer and said polycrystalline semiconductor layer.

6. A display apparatus according to claim 5, wherein said insulating layer comprises silicon oxide and said blocking layer comprises silicon nitride.

7. A display apparatus according to claim 5, wherein either a constant voltage or a signal identical to that of a scanning line for scanning the driving element formed on the upper layer of the light shielding layer is applied to said light shielding layer.

8. A display apparatus according to claim 7, wherein said constant voltage is a control voltage applied to the pixels having said driving element.

9. An active matrix type display apparatus comprising;
a pixel region and a driver region formed over a same substrate; a plurality of pixels arranged in said pixel region, each of said plurality of pixels having a pixel region transistor and a display element; and a plurality of driver region transistors for outputting a signal for driving each of said pixels in said pixel region are arranged in said driver region; wherein
a same polycrystalline semiconductor material is used for active layers of the pixel region transistors and the driver region transistors both of which are formed as top gate type transistors over said substrate;
a blocking layer and an insulating layer are formed in that order from a side of said substrate under polycrystalline semiconductor active layer of said pixel region transistors and said driver region transistor, said blocking layer preventing impurities from diffusing and said insulating layer formed so as to make contact with said polycrystalline semiconductor active layer, an interface state density between said insulating layer and said polycrystalline semiconductor layer being lower than that between said blocking layer and said polycrystalline semiconductor active layer; and
a light shielding layer is provided under said polycrystalline semiconductor active layer of said pixel region transistors so as to sandwich said insulating layer and said blocking layer.

10. An active matrix type display apparatus according to claim 9, wherein said light shielding layer has tapered side broadening toward the substrate side.

11. An active matrix type display apparatus according to claim 9, wherein either a constant voltage or a signal identical to that of a scanning line for scanning a thin film transistor of said pixel region formed over the light shielding layer is applied to said light shielding layer.

12. A manufacturing method of a display apparatus comprising: the steps of
forming a light shielding layer over a substrate;
forming a blocking layer above said substrate for preventing impurities from diffusing so as to cover said light shielding layer;
forming, over said blocking layer, an insulating layer having an interface state density with a polycrystalline semiconductor that is lower than that between said blocking layer and said polycrystalline semiconductor; forming an amorphous semiconductor layer on said insulating layer;
polycrystallize said amorphous semiconductor layer by annealing; and
forming a driving element employing an obtained polycrystalline semiconductor layer as an active layer.

13. A method of manufacturing a display apparatus according to claim 12, wherein said light shielding layer is formed in a tapered shape in which the edges of said light shielding layer are broader toward the substrate side.

14. A method of manufacturing a display apparatus according to claim 12, wherein the steps from forming said blocking layer to forming said amorphous semiconductor layer are carried out in sequence and within in a single apparatus.

15. A manufacturing method of a display apparatus according to claim 12, wherein said blocking layer is formed using silicon nitride as a principle component, and said insulating layer is formed using silicon oxide as a principle component.

16. A manufacturing method of a display apparatus according to claim 12, wherein said light shielding layer is patterned in the pixel region and the driver region formed on the same substrate in such a manner that the light shielding layer is selectively left under a region on which said polycrystalline semiconductor layer constituting the driving element in said pixel region is formed, and removed from a region on which said polycrystalline semiconductor layer constituting the driving element in said driver region and polycrystallized at a same time from a same material with the driving element in said pixel element is formed.
